(19) United States
(12) Patent Application Publication
(10) Pub. No.: US 2026/0247936 A1
(43) Pub. Date: Aug. 20, 2026

(54) METHODS FOR THE PROVISION OF A COATED GRAPHENE LAYER STRUCTURE ON A SILICON-CONTAINING WAFER

(71) Applicant: PARAGRAF LIMITED, Somersham (GB)

(72) Inventors: Ivor GUINEY, Somersham (GB); Andrew N. MACINNES, Somersham (GB)

(73) Assignee: PARAGRAF LIMITED, Somersham (GB)

(21) Appl. No.: 19/164,465

(22) PCT Filed: Mar. 11, 2024
(86) PCT No.: PCT/EP2024/056412

§ 371 Date: Sep. 11, 2025

(30) Foreign Application Priority Data
Mar. 14, 2023 (GB) 2303727.8

(51) Int. Cl. H10P 90/00; C23C 16/26; C30B 25/18; C30B 29/40; C30B 29/68; H10D 30/01

(52) U.S. Cl. CPC H10P 90/212; C23C 16/26; C30B 25/18; C30B 29/403; C30B 29/68; H10D 30/017; H10P 90/1914

(57) ABSTRACT

There is provided a method for the provision of a coated graphene layer structure (410) on a silicon-containing wafer (435), the method comprising: (1) providing a wafer stack (420) comprising, in order, a transparent substrate (400), a nitride layer (405), a graphene layer structure (410) and a dielectric passivation layer (415), wherein the dielectric passivation layer (415) has an exposed upper surface; (2) forming or adhering (300) a further layer (435) onto the exposed upper surface of the dielectric passivation layer (415); and (3) removing the substrate (400) by laser lift-off 305 to expose a surface of the nitride layer (405) distal from the graphene layer structure (410); wherein the nitride layer (405) of the wafer stack (420) comprises a first surface directly adjacent the substrate (400) and a second surface directly adjacent the graphene layer structure (410), wherein the first and second surfaces are each independently formed of aluminium nitride or boron nitride; and wherein: the method further comprises wafer bonding (130, FIG. 2) the exposed surface of the nitride layer to a surface (235b′, FIG. 2) of a silicon-containing wafer (235, FIG. 2) after the step (125, FIG. 2) of removing the substrate (225, FIG. 2); or the step of forming or adhering comprises wafer bonding (300), and the further layer is a silicon-containing wafer (435). The laminate (440) is suitable for the manufacture of an electronic device (460).

The present invention relates to methods for the provision of a coated graphene layer structure on a silicon-containing wafer, and a graphene-containing laminate and an electronic device obtainable therefrom. More particularly, the present invention relates to a method comprising a step of laser lift-off to separate a nitride layer together with a graphene layer structure from a transparent substrate, and a step of wafer bonding to a silicon-containing wafer.

Two-dimensional (2D) materials, in particular graphene, and their electronic devices are currently the focus of intense research and development worldwide. 2D-materials have been shown to have extraordinary properties, both in theory and in practice which has led to a deluge of products incorporating such materials which include coatings, batteries and sensors to name but a few. Graphene is most prominent and is being investigated for a range of potential applications. Most notable is the use of graphene in electronic devices and their constituent components which includes transistors, diodes, LEDs, photovoltaic cells, Hall-effect sensors, current sensors, biosensors and the like.

Accordingly, there are a wide range of electronic devices known in the prior art which have integrated graphene layer structures (single layer or multi-layer graphene) and/or other 2D-materials as key materials for delivering improvements in such devices over earlier devices and electronic products. These include structural improvements through the use of thinner and lighter materials (which can give rise to flexible electronics) as well as performance improvements such as increased electrical and thermal conductance leading to greater operating efficiencies.

The preparation of sufficiently large area graphene with high uniformity has been a major problem in the art which has hindered the uptake of graphene in commercial processes and electronic devices. The standard in the art is to manufacture graphene by CVD on copper foils or other catalytic metal substrates. A significant proportion of research and development has since focussed on the need to optimise the process by which graphene is transferred from such substrates to those of interest for electronic devices (i.e. non-metallic substrates, for example semiconductors such as silicon and insulators such as sapphire).

However, the inventors found that graphene grown on copper is inevitably contaminated, if not with copper, at least with the additional materials which are essential to effect the transfer. These include transfer polymers such as PMMA, metal etchants and solvents to remove the polymer. Polymer residues are however never fully removed and graphene provided by such methods cannot be devoid of transfer polymers and/or copper. Additionally, the physical manipulation of the graphene during transfer leads to defects in the atomically thin material. The use of copper at any stage of the manufacturing process is also a barrier to integration with standard silicon wafer fabrication (i.e. with CMOS wafers) and therefore a barrier to the commercial uptake of graphene and 2D materials in mass-produced electronic devices.

Nanomaterials, 2021, 11, 2837 “Graphene Transfer: A Physical Perspective” provides a recent review of graphene transfer methods.

Nature Communications, 2021, 12, 917 “Large-area integration of two-dimensional materials and their heterostructures by wafer bonding” relates to a method of transferring CVD graphene from copper foils to silicon wafers.

Adv. Mater. Technol. 2023, 2201587 “Assessment of Wafer-Level Transfer Techniques of Graphene with Respect to Semiconductor Industry Requirements” is a recent example of graphene transfer techniques at wafer-scale, both of which are observed to result in appreciable copper contamination.

US 2013/240839 A1 relates to graphene-channel based devices and techniques for the fabrication thereof which may include a wafer bonding step to form an oxide-to-oxide bond between an oxide coated graphene layer and a counterpart CMOS device wafer.

US 2013/256629 A1 relates to a graphene semiconductor device and a method of manufacturing a graphene semiconductor device which may include attaching a semiconductor layer of a laminate further comprising a sacrificial substrate and a sacrificial layer therebetween to a surface of a graphene layer and etching the sacrificial layer in order to remove the sacrificial substrate.

It is also known in the art that graphene may be synthesised, manufactured, formed, directly on non-metallic surfaces of substrates. The present inventors have found that the most effective method for manufacturing high-quality graphene, especially directly on such non-metallic surfaces, is that disclosed in WO 2017/029470 (the contents of which is incorporated herein by reference), which provides two-dimensional materials, particularly graphene, with a number of advantageous characteristics including very good crystal quality, large material grain size, minimal material defects, large sheet size and no metal or organic polymer contamination. The method of WO 2017/029470 may be performed using vapour phase epitaxy (VPE) systems and metal-organic chemical vapour deposition (MOCVD) reactors.

Whilst the method of WO 2017/029470 enables the production of high-quality graphene with excellent uniformity and a constant number of layers (as desired) across its whole area on the substrate without additional carbon fragments or islands, the inventors have found that this introduces problems with the formation of dielectric layers on the graphene (for example, by atomic layer deposition). Such problems are of a much lesser concern, or even not encountered in the prior art where graphene is transferred due to the inevitable presence of defects which function as nucleation sites. As such, the inventors have found that there is a significantly greater challenge associated with dielectric layer formation on the pristine surface of CVD-grown graphene.

WO 2022/175273 A1 (the contents of which is incorporated herein by reference in its entirety), as well as the corresponding GB 2603905 and TW 202246175, is a publication originating from the present inventors which relates to the formation of a thin graphene-containing conductive substrate obtainable by etching a sacrificial silicon wafer away from a graphene layer structure formed on an insulative layer that is itself formed on the silicon wafer.

US 2011/068320 A1 relates to an electronic device that includes an under-layer constructed of highly ordered crystalline material having a high dielectric constant and an over-layer constructed of a crystalline material having a high dielectric constant, and a layer of graphene located between the over-layer and the under-layer. This document does not disclose a method of manufacture but discloses that these layers can be formed on a substrate material.

US 2019/273166 A1 provides a microelectronic device which includes a gated graphene component. The gated graphene component includes a graphitic layer containing one or more layers of graphene, and further includes a patterned hexagonal boron nitride (hBN) layer on the graphitic layer over the channel region, and a gate over the patterned hBN layer above the channel region.

CN 110828550 A relates to the construction of a boron nitride/graphene heterojunction, the device characterized in that the angle of rotation between the hexagonal boron nitride layer and the graphene layer is between 5°to 15°. The boron nitride/graphene heterojunction is prepared by mechanical transfer method and conventional micro-nano processing technology.

US 2020/403068 A1 relates to a chemically-doped graphene transistor which in one embodiment, is made by first depositing n-type graphene on the substrate (e.g. sapphire etc.), or on a semiconductor layer formed on the substrate (e.g. AlN).

IEEE Spectrum, 2020, 57(2), 44 “Atom-thick transistors” provides a review of devices made with 2D materials.

As well as the integration of high-quality 2D materials, there remains an ongoing need for technologies which enable the provision of high-quality semiconductors in general, particularly thin layers (e.g. nm or μm scale, generally up to about 100 μm). A recent overview of transfer techniques for heterogenous integration of ultrathin semiconductor layers is given in Nanomaterials, 2021, 11, 842 “Layer-Scale and Chip-Scale Transfer Techniques for Functional Devices and Systems: A Review”.

One such technique known to those skilled in the art is “laser lift-off” (LLO). A review of LLO is given in Physics Procedia, 2013, 41, 241 “Large-area laser-lift-off processing in microelectronics”. This technique is most commonly encountered in the field of light emitting diodes (LEDs) in which LLO is in most circumstances used to detach epitaxial GaN layers from sapphire substrates. This can be achieved using a 248 nm wavelength laser, illuminating the GaN through the sapphire wafer.

As is known in the art, the wavelength of laser is selected based on the band gaps of the materials so as to be absorbed by only one material. The surface of the absorbing layer decomposes thereby detaching the layers. For example, GaN decomposes to metallic gallium and nitrogen gas. Whilst GaN is invariably the material of choice in the art for the LLO process, other layers such as AlN can be used. Phys. Status Solidi C, 2012, 9, 753 “Laser lift-off of AlN/sapphire for UV light-emitting diodes” describes a process of LLO of AlN/sapphire using a 193 nm laser.

Other techniques include 2D layer-assisted delamination whereby the weak Van der Waals adhesion to the semiconductor layer allows for mechanical delamination. Adv. Funct. Mater., 2023, 2209880 “Recent Advances in Mechanically Transferable III-Nitride Based on 2D Buffer Strategy” provides a recent overview of 2D material-assisted exfoliation. Nature, 2012, 484, 223 “Layered boron nitride as a release layer for mechanical transfer of GaN-based devices” discloses using h-BN as an alternative to laser lift-off which provides a buffer layer for the growth of high-quality GaN-based semiconductors and a shear plane to release the resulting devices. Materials, 2020, 13, 5118 “Epitaxial Growth of GaN on Magnetron Sputtered AlN/Hexagonal BN/Sapphire Substrates” provides an example of using magnetron sputtered AlN on h-BN as a buffer layer to facilitate the growth of high-quality GaN.

The present invention aims to overcome, or at least reduce, the aforementioned combination of problems in the prior art so as to allow for the wafer-scale integration of high-quality, defect and contamination free, graphene and high-quality dielectrics into electronic devices, or to at least provide a commercially viable alternative thereto.

In a first aspect, the present invention provides a method for the provision of a coated graphene layer structure on a silicon-containing wafer, the method comprising:
(i) providing a wafer stack comprising, in order, a substrate having a band gap of 6.5 eV or more, a nitride layer, a graphene layer structure and a dielectric passivation layer, wherein the dielectric passivation layer has an exposed upper surface;
(ii) forming or adhering a further layer onto the exposed upper surface of the dielectric passivation layer;
(iii) removing the substrate by laser lift-off to expose a surface of the nitride layer distal from the graphene layer structure; and
(iv) wafer bonding the exposed surface of the nitride layer to a surface of a silicon-containing wafer;
wherein the nitride layer of the wafer stack comprises: a first surface adjacent the substrate and a second surface adjacent the graphene layer structure, wherein the first and second surfaces are each independently formed of aluminium nitride or boron nitride.

In a second aspect, the present invention provides a method for the provision of a coated graphene layer structure on a silicon-containing wafer, the method comprising:
(I) providing a wafer stack comprising, in order, a substrate having a band gap of 6.5 eV or more, a nitride layer, a graphene layer structure and a dielectric passivation layer, wherein the dielectric passivation layer has an exposed upper surface;
(II) wafer bonding the exposed upper surface of the dielectric passivation layer to a surface of a silicon-containing wafer; and
(III) removing the substrate by laser lift-off to expose a surface of the nitride layer distal from the graphene layer structure;
wherein the nitride layer of the wafer stack comprises a first surface directly adjacent the substrate and a second surface directly adjacent the graphene layer structure, wherein the first and second surfaces are each independently formed of aluminium nitride or boron nitride.

Thus, the first and second aspects share special features which are novel over the prior art so as to provide a coated graphene layer structure on a silicon-containing wafer through a step of wafer bonding. Accordingly, the present invention equally relates to a method for the provision of a coated graphene layer structure on a silicon-containing wafer, the method comprising:
(1) providing a wafer stack comprising, in order, a transparent substrate, a nitride layer, a graphene layer structure and a dielectric passivation layer, wherein the dielectric passivation layer has an exposed upper surface;
(2) forming or adhering a further layer onto the exposed upper surface of the dielectric passivation layer; and
(3) removing the substrate by laser lift-off to expose a surface of the nitride layer distal from the graphene layer structure;
wherein the nitride layer of the wafer stack comprises a first surface directly adjacent the substrate and a second surface directly adjacent the graphene layer structure, wherein the first and second surfaces are each independently formed of aluminium nitride or boron nitride; and
wherein:
   the method further comprises wafer bonding the exposed surface of the nitride layer to a surface of a silicon-containing wafer after the step of removing the substrate (in which case the further layer is preferably a sacrificial layer which is subsequently removed, for example a metal layer); or
   the step of forming or adhering comprises wafer bonding, and the further layer is a silicon-containing wafer.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

Consequently, the following features as described herein apply equally to both the first and the second aspect unless the context clearly dictates otherwise (e.g. the nature of the further layer and/or which surface is wafer bonded to a silicon-containing wafer). Similarly, in a further aspect, the present invention provides a graphene-containing laminate obtainable by the methods described herein such that any feature described in respect of the method may describe the graphene-containing laminate (or any subsequent electronic device manufactured using the method or graphene-containing laminate).

The present invention relates to methods for the provision of a coated graphene layer structure on a silicon-containing wafer. The graphene layer structure in the resulting product (i.e. a graphene-containing laminate) is coated across its entire surface with a further layer, either a nitride layer or dielectric passivation layer as described herein.

In a first step, the method comprises providing a wafer stack comprising, in order, a substrate, a nitride layer, a graphene layer structure and a dielectric passivation layer, wherein the dielectric passivation layer has an exposed upper surface.

As is known in the art of semiconductor fabrication, the terms substrate and wafer may be used interchangeably. As such, the term “wafer stack” is used to define a wafer or substrate which comprises a substrate having thereon the layers described forming a stack. As will be appreciated, a given wafer or substrate may still be referred to as a wafer throughout the process of forming additional layers to form a laminated wafer, and ultimately electronic devices therefrom.

The substrate is a transparent substrate so as to allow for the subsequent laser lift-off step. That is, in order to allow the laser to reach and be absorbed by the nitride layer, the substrate is transparent to lasers of such wavelength. As such, the substrate may have a band gap of 6.5 eV or more, the band gap of the nitride layer (i.e. AlN or BN) being lower than this. As a result, the laser will be absorbed by the nitride layer and decompose to separate the nitride layer from the substrate. The band gap of the substrate may preferably be 7.0 eV or more, or 8.0 eV or more. Sapphire is particularly preferred as a transparent substrate and typically has a band gap of a least about 9.0 eV. Whilst the following description focusses on the use of sapphire, other transparent substrates may be used, commonly inorganic oxides and fluorides (such as silicon oxide which has a band gap similar to that of sapphire, or YSZ).

Sapphire wafers are well-known in the art and provide an excellent support for the wafer stack. As the support, the sapphire is generally much thicker than the layer subsequently formed thereon. Typically, a support layer has a thickness of 250 μm to 1.5 mm, for example from 400 μm to 1 mm. The surface of the sapphire substrate adjacent the nitride layer may have a particular crystallographic orientation. For example, c-plane (<0001>) or r-plane (<1-102>) may be preferred for epitaxial growth of the nitride layer.

The nitride layer of the wafer stack comprises a first surface adjacent (i.e. directly next to) the sapphire substrate and a second surface directly adjacent the graphene layer structure. That is, the nitride layer may be formed of a single material (in which case the first and second surfaces are formed of said single material), or may consist of two or more sub-layers whereby the first surface is provided by a first sub-layer and the second surface provided by a second sub-layer. In accordance with the present invention, it is beneficial for the surfaces which are adjacent the sapphire substrate and the graphene layer structure to be formed of either aluminium nitride or boron nitride. As described further herein, these materials are particularly suited to the present process and may be used to address some of the problems associated with incorporating two-dimensional materials into silicon-based processes. As such, the first and second surfaces are each independently formed of aluminium nitride or boron nitride.

Accordingly, in some embodiments, the nitride layer consists of aluminium nitride or boron nitride. It is generally preferred that the nitride layer at least comprises a sub-layer of aluminium nitride. As such, in some preferred embodiments, the nitride layer is formed of two sub-layers: a first sub-layer of aluminium nitride or boron nitride providing the first surface and a second sub-layer of aluminium nitride or boron nitride providing the second surface (wherein the first and second sub-layer are different).

In some embodiments the nitride layer includes one or more further sub-layers between the first and second sub-layers, wherein the further sub-layers are formed of nitride. For example, the nitride layer may comprise one further sub-layer and/or be formed of a metal nitride such as gallium nitride. In one preferred embodiment, the one or more further sub-layers comprise, or otherwise take the form of, a multiple quantum well (MQW) structure. MQWs are well-known, and can include, by way of example only, a plurality of thin GaN layers each separated from one another by AlN or AIGaN or InGaN. Suitable materials and thicknesses are well-known to those skilled in the art, and each GaN layer of an MQW, for example, may typically have a thickness of 3 nm to 20 nm.

Generally, the thickness of such a nitride layer comprising three or more sub-layers is thicker than that formed of a single material, or two sub-layers. The thickness of the nitride layer is generally up to 10 μm, though this may be much thinner in the absence of a middle sub-layer.

An aluminium nitride layer of the wafer stack preferably has a thickness of at least 100 nm (either as a single layer or sub-layer), such as at least 150 nm. Generally, the thickness of the layer is at most 5 μm, preferably at most 2 μm. As described herein, the nitride layer may be etched to reduce such a thickness which is particularly useful to reduce the thickness of an aluminium nitride layer.

A boron nitride layer may have an equivalent thickness as the aluminium nitride layer, though this can be dependent on the crystal structure of the boron nitride. Aluminium nitride is invariably provided in its wurtzite crystal structure. Boron nitride may be provided in an equivalent wurtzite crystal structure (w-BN) or may be provided in cubic form (c-BN), analogous to diamond. Boron nitride is preferably provided in hexagonal form (h-BN) which is a known two-dimensional form, analogous to graphene. In such circumstance, the thickness of the boron nitride layer may be much thinner, for example from about 0.6 nm to 100 nm, preferably from about 0.9 nm to 20 nm. The thickness of at least 0.3 nm corresponds essentially to at least a monolayer of h-BN, which may be preferred for the second sub-layer adjacent the graphene layer structure. However, a thicker boron nitride layer may be required adjacent the sapphire substrate to allow for the laser ablation of the layer at the interface with the sapphire substrate whilst retaining a portion for incorporation into electronic devices.

Preferably the nitride layer of the wafer stack is provided by forming the nitride layer directly on the sapphire substrate by epitaxy. Generally, the nitride layer, and each sub-layer when formed of sub-layers, is preferably formed by MOCVD. Such techniques for forming nitride layers are well-known in the art, particularly on sapphire which allows for high-quality AlN and BN growth. Furthermore, forming the layers by MOCVD allows for an in-situ formation of a graphene layer structure directly thereafter which is beneficial for high-quality graphene formation. As described herein with respect to graphene, and in particular in respect of h-BN, such steps avoid the need to transfer the two-dimensional materials which avoids introducing contaminants and defects.

As such, it is especially preferred that the wafer stack is provided by forming the graphene layer structure by CVD directly on the nitride layer (i.e. on the nitride layer of a “first” wafer that comprises a sapphire substrate and a nitride layer). The nitride layer as described herein is particularly beneficial for CVD growth of graphene since the layer is able to withstand the high temperatures required for CVD and support the growth of graphene. In particular, the inventors have found that forming graphene on an exposed surface of GaN, for example, risks decomposition of the growth surface. Therefore the method allows for the integration of high-quality graphene into silicon-based wafers together with the nitride layer.

Graphene is a very well-known two-dimensional material referring to an allotrope of carbon comprising a single layer of carbon atoms in a hexagonal lattice. A graphene layer structure, as used herein, refers to one or more layers of graphene. Accordingly, the present invention relates to the formation of a monolayer of graphene as well as multilayer graphene. A graphene layer structure preferably has from 1 to 10 monolayers of graphene. In many subsequent applications of a graphene-containing laminate for forming an electronic device, one monolayer of graphene is particularly preferred. Accordingly, the graphene layer structure is preferably a graphene monolayer. Nevertheless, multilayer graphene may be preferable for certain applications and 2 or 3 layers of graphene may be preferred.

CVD refers generally to a range of chemical vapour deposition techniques, each of which involve deposition to produce thin film materials such as two-dimensional crystalline materials like graphene. Volatile precursors, those in the gas phase or suspended in a gas, are decomposed to liberate the necessary species to form the desired material, carbon in the case of graphene. CVD as described herein is intended to refer to thermal CVD such that the formation of graphene from the decomposition of a carbon-containing precursor is the result of the thermal decomposition of said carbon-containing precursor. Forming may be considered synonymous with synthesising, manufacturing, producing, depositing and growing.

Preferably, the method involves forming graphene by thermal CVD such that decomposition is a result of heating the carbon-containing precursor. Preferably, the temperature of the growth surface (i.e. the exposed upper surface of the wafer) during CVD is from 700° C. to 1350° C., preferably from 800° C. to 1250° C., more preferably from 1000° C. to 1250° C. The inventors have found that such temperatures are particularly effective for providing graphene growth directly on the nitride layer by CVD. Preferably, the CVD reaction chamber used in the method disclosed herein is a cold-walled reaction chamber wherein a heater coupled to the wafer is the only source of heat to the chamber.

In a preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate/wafer and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface. Accordingly, such an embodiment involves a “vertical” arrangement whereby the plane containing the precursor entry points is substantially parallel to the plane of the substrate growth surface (i.e. the nitride layer).

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C. For the avoidance of doubt, the addition of precursor at a temperature above ambient does not constitute heating the chamber, since it would be a drain on the temperature in the chamber and is responsible in part for establishing a temperature gradient in the chamber.

Preferably, a combination of a sufficiently small separation between the growth surface and the plurality of precursor entry points and the cooling of the precursor entry points, coupled with the heating of the growth surface to within a decomposition range of the precursor, generates a sufficiently steep thermal gradient extending from the surface to the precursor entry points to allow graphene formation on the surface. As disclosed in WO 2017/029470, very steep thermal gradients may be used to facilitate the formation of high-quality and uniform graphene directly on such non-metallic substrates, preferably across the entire surface of the substrate. The substrate/wafer may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco® TurboDisk reactor.

Consequently, in a particularly preferred embodiment wherein the method of the present invention involves using a method as disclosed in WO 2017/029470, forming the graphene layer structure on the growth surface by CVD comprises:
providing the first wafer on a heated susceptor in a close-coupled reaction chamber, the close-coupled reaction chamber having a plurality of cooled inlets arranged so that, in use, the inlets are distributed across the growth surface and have constant separation from the first wafer;
cooling the inlets to less than 100° C.;
introducing a carbon-containing precursor in a gas phase and/or suspended in a gas through the inlets and into the close-coupled reaction chamber; and
heating the susceptor to achieve a growth surface temperature of at least 50° C. in excess of a decomposition temperature of the precursor, to provide a thermal gradient between the growth surface and inlets that is sufficiently steep to allow the formation of graphene from carbon released from the decomposed precursor;
wherein the constant separation is less than 100 mm, preferably less than 25 mm, even more preferably less than 10 mm.

In another particularly preferred embodiment wherein the method involves using a method as disclosed in WO 2019/138231 (the contents of which is incorporated herein in its entirety), forming the graphene layer structure on the growth surface by CVD comprises:
providing the first wafer on a heated susceptor in a reaction chamber, the reaction chamber having a plurality of inlets arranged so that, in use, the inlets are distributed across the growth surface and have constant separation from the first wafer;
rotating the heated susceptor at a rotation rate of at least 600 rpm, preferably up to 3000 rpm;
introducing a carbon-containing precursor in a gas phase and/or suspended in a gas through the inlets and into the reaction chamber; and
heating the susceptor to achieve a growth surface temperature of at least 50° C. in excess of a decomposition temperature of the precursor;
wherein the constant separation is at least 12 cm, preferably up to 20 cm.

The most common carbon-containing precursor in the art for graphene growth is methane (CH₄). The inventors have found that it is preferable that the carbon-containing precursor used to form graphene is an organic compound, that is, a chemical compound, or molecule, that contains a carbon-hydrogen covalent bond, which comprises two or more carbon atoms. Such precursors have a lower decomposition temperature than methane which advantageously allows the growth of graphene at lower temperatures when using the method described herein which is particularly advantageous for growth on such non-metallic nitride surfaces. Preferably, the precursor is a liquid when measured at 20° C. and 1 bar of pressure (i.e. under standard conditions according to IUPAC). Accordingly, the precursor preferably has a melting point that is below 20° C., preferably below 10° C., and has a boiling point above 20° C., preferably above 30° C. Liquid precursors are simpler to store and handle when compared to gaseous precursors which typically require high pressure cylinders. Due to their relatively reduced volatility when compared to gaseous precursors, they present a lower safety risk during large scale manufacture. Increasing the molecular weight of the compounds beyond about C₁₀, particularly beyond about C₁₂, typically reduces their volatility and suitability for CVD growth of graphene on non-metallic. Preferably, the organic compound consists of carbon and hydrogen and, optionally, oxygen, nitrogen, fluorine, chlorine and/or bromine.

As discussed above, the method described herein preferably uses a carbon-containing precursor that is an organic compound comprising two of more carbon atoms, i.e. a C₂₊ organic compound.

Preferably, the carbon-containing precursor is a C₃-C₁₂ organic compound consisting of carbon and hydrogen and, optionally, oxygen, nitrogen, fluorine, chlorine and/or bromine. As described herein, a Cn organic compound refers to one comprising “n” carbon atoms and optionally one or more further hetero atoms oxygen, nitrogen, fluorine, chlorine and/or bromine. Preferably, the organic compound comprises at most one heteroatom as such organic compounds are typically more readily available in high purity, for example ethers, amines, and haloalkanes.

The carbon-containing precursor is preferably a C₃-C₁₀ organic compound consisting of carbon and hydrogen and, optionally, oxygen, nitrogen, fluorine, chlorine and/or bromine, even more preferably a C₆-C₉ organic compound. In a preferred embodiment, the precursor does not comprise a heteroatom, such that the precursor consists of carbon and hydrogen. In other words, preferably the carbon-containing precursor is a hydrocarbon, preferably an alkane.

It is also preferable that the organic compound comprise at least two methyl groups (—CH₃). Particularly preferred organic compounds for use as carbon-containing precursors, and methods of forming graphene therefrom by CVD, are described in GB 2604377 (the contents of which is incorporated herein in its entirety). The inventors have found that when forming graphene directly on non-metallic substrates, precursors beyond the traditional hydrocarbons methane and acetylene allow for the formation of even higher quality graphene. Preferably, the precursor is a C₄-C₁₀ organic compound, more preferably the organic compound is branched such that the organic compound at least three methyl groups.

Without wishing to be bound by theory, the inventors believe that heavier organic compounds (i.e. those greater than C₁₂, or greater than C₁₀, and/or those which are solid under standard conditions) provide a “less pure” source of CH₃ radicals. With an increase in size and complexity of the organic compound there is an increase in the number of decomposition pathways and the possibility of a greater range of by-products which can lead to graphene defects. The organic compounds as described herein provide a balance of being large enough to deliver the required, and a desirably high fraction of, methyl groups under pyrolysis. The organic compounds are however small enough to be simple to purify, particularly where the precursor is liquid, and have a relatively simple pyrolysis chemistry with limited decomposition pathways. Furthermore, unlike heavier compounds, they do not so readily condense within the reactor plumbing which is a particular disadvantage for the industrial production of graphene due to the greater risk of reactor downtime.

The wafer stack further comprises a dielectric passivation layer on the graphene layer structure which provides an exposed upper surface of the wafer stack. Therefore, providing the wafer stack, particularly where the graphene layer structure is formed directly on a first wafer by CVD, preferably comprises a step of forming a further layer comprising dielectric material on the graphene layer structure.

One advantage of the second aspect lies in the provision of a high-quality nitride layer on pristine graphene through having avoided the need to form the layer on graphene. However, the present invention still requires the formation of a dielectric passivation layer on the graphene prior to the wafer-bonding step to protect the graphene. In the second aspect, this layer subsequently simply forms part of the underlying support after having been “flipped” though still provides a passivation layer in the laminate resulting from the method of the first aspect. As described herein for the nitride layer, the dielectric passivation layer may consist of a single material, or two or more sub-layers. Preferably the dielectric passivation layer is formed of inorganic oxide, nitride, carbide, fluoride or sulphide, preferably metal oxide. Preferably the dielectric passivation layer has a thickness of from 0.5 nm to 500 nm, preferably from 1 nm to 100 nm.

The inventors have found that a further layer may be formed on the graphene layer structure so as to dope the graphene. The further layer preferably comprises a dielectric metal oxide, preferably molybdenum oxide. Another preferred group of materials are transition metal dichalcogenides (TMDs) which are well-known two-dimensional materials (most commonly molybdenum or tungsten, disulfide, diselenide or ditelluride). TMDs and molybdenum oxide are particularly preferred materials, especially molybdenum oxide, that the inventors have found are suited for counter doping CVD-grown graphene (which is typically n-type whereas the intrinsic doping of transferred graphene is typically p-type due to exposure to catalytic metal substrates and/or transfer polymers and/or wet processing chemicals). Accordingly, it is preferred that the dielectric passivation layer comprises a first sub-layer formed of a transition metal dichalcogenide or molybdenum oxide, wherein the first sub-layer is provided on the graphene layer structure. A second sub-layer may be formed of a conventional inorganic oxide, nitride, carbide, fluoride or sulphide, for example aluminium oxide.

The thickness of such a first sub-layer is preferably less than 5 nm, more preferably less than 3 nm, for example from 0.1 nm to 5 nm. The inventors have found that this thickness may be used to control the extent of doping of the graphene layer structure to arrive the desired charge carrier concentration whereby a greater thickness leads to more p-doping. The desired nominal thickness can be achieved through use of a Quartz Crystal Microbalance (QCM) during formation, particularly of molybdenum oxide, which provides the skilled person with an in-situ measurement of the amount of material deposited when carrying out the method. The thickness of the layer is therefore a mean average thickness of the layer. The thickness may then equally be readily determined by those skilled in the art using conventional techniques, for example AFM. The further layer may be deposited using conventional means in the art, for example PVD techniques such as sputtering or evaporation (e.g. thermal evaporation). Techniques for forming TMDs are well-known in the art.

In some embodiments the graphene layer structure has a charge carrier concentration of less than 5×10¹² cm⁻², preferably less than 2×10¹² cm−⁻², more preferably less than 10¹² cm⁻², as a result of the combination of materials and method of manufacture described herein. The charge carrier concentration is that measured at ambient conditions (e.g. 25° C.) after manufacture is complete. A device may be manufactured incorporating the graphene-containing laminate and, as such, the charge carrier concentration refers to that of the final, as-manufactured laminate or device.

The methods further comprise a step of forming or adhering a further layer onto the exposed upper surface of the dielectric passivation layer (i.e. onto the wafer stack), followed by removing the sapphire substrate by laser lift-off to expose a surface of the nitride layer distal from the graphene layer structure.

In accordance with the first aspect, the method further comprises wafer bonding the exposed surface of the nitride layer to a surface of a silicon-containing wafer after the step of removing the sapphire wafer. In this embodiment, it is generally preferred that the further layer is a sacrificial layer whereby the method subsequently comprises removing the further layer after the step of wafer bonding. In some preferred embodiments, the layer is an etchable layer, for example formed of metal. Copper is a common metal to be used in LLO processes for GaN-based LED manufacture. However, in order to avoid copper contamination in CMOS processes, other metals such as aluminium, titanium and/or nickel may be preferred. Such layers may be formed by deposition across the exposed upper surface of the dielectric passivation layer. Other techniques known in the art include electroplating. Alternatively, the metal layer may be adhered to the exposed upper surface by wafer bonding, for example and optionally via a bonding layer of indium, nickel, gold or palladium.

In some embodiments, the further layer is completely removed. However, it may also be preferred to etch the metal layer to form a gate contact for an electronic device such as a transistor.

In accordance with the second aspect, the step of forming or adhering comprises wafer bonding, and the further layer is a silicon-containing wafer thereby bonding the dielectric passivation layer with the surface of the silicon-containing wafer.

The silicon-containing wafer of either aspect is not particularly limited. In some preferred embodiments, the wafer is a CMOS wafer. Such a wafer is typically a silicon wafer which has associated circuitry embedded within together with appropriately patterned dielectric layers. A suitable silicon-containing wafer may also comprise regions or channels of embedded materials, for example waveguide materials, such as silicon nitride embedded within silicon dioxide, which are suitable for electro-optic modulators and photodetectors (which may be provided on a silicon support). The exposed contact surface of the wafer may also be formed of regions of different materials. For example, a silicon support may have a surface comprising a patterned region(s) of the silicon and region(s) of embedded dielectric material. Such a wafer may be suitable for the manufacture of a graphene barristor. The silicon-containing wafer, or a silicon support may preferably be “pure” silicon (essentially consisting of silicon, doped or undoped). Where the silicon-containing wafer comprises a layer such as silicon oxide or silicon nitride on a silicon support, the exposed surface of the layer is distal from the silicon support (the opposite non-exposed surface of the layer being that which is in contact with the support). The silicon oxide and/or silicon nitride may have a thickness of from 50 to 500 nm. In some embodiments for the manufacture of very thin electronic devices, the methods preferably further comprise a step of removing the silicon support after the step of wafer bonding.

It is advantageous that the silicon-containing wafer can comprise metal contacts at its exposed surface (together with any associated circuitry embedded therein). This is particularly beneficial where a CVD grown graphene layer structure is employed since growth by MOCVD processes as described herein, but directly onto metallic contacts rather than a non-metallic surface, is not desirable. As such, the method allows for the incorporation of graphene formed by such methods into devices having underlying contacts.

Wafer-bonding processes are generally well-known. Preferably, the step of wafer-bonding is direct bonding (which may also be referred to a fusion bonding). Such processes are typically used to bond layers of, for example, two dielectric oxides, nitrides and/or metal contacts whereby the process results in chemical bonds between the two surfaces as a result of the two surfaces having available bonding sites for hydrogen and/or covalent bonding, and being sufficiently clean and smooth.

Such a step may be carried out in a conventional wafer bonding apparatus. Typically, the process comprises heating the contacted wafers, optionally under application of a force. It is particularly preferred that the step is carried out under vacuum so as to exclude as far as possible any oxygen and/or moisture from the surface of the two wafers.

Preferably, the wafer-bonding is performed at a temperature of from 100° C. to 850° C., preferably from 150° C. to 450° C., such as from 200° C. to 400° C. These temperatures are generally suitable due to the layers protecting the graphene, such as molybdenum oxide, since this reduces the risk of damaging the graphene and the further layer facilitates the wafer bonding. A maximum of 850° C. is preferred where the silicon-containing wafer is a CMOS wafer. Typical dielectric layers on a silicon support include silicon oxide, silicon nitride, alumina, hafnia and the like, and as described herein, may also incorporate metal contacts exposed at the surface and metal vias embedded therein. A force of at least 100 N, such as at least 500 N may be applied during wafer-bonding, and/or up to 10 kN in some embodiments.

The method may further comprise a step of patterning either wafer described hereinabove prior to wafer bonding, in particular the layers provided on the support (e.g. the sapphire support of the wafer stack, or a support provided by the further layer in accordance with the first aspect, either of which may be referenced to as the first wafer, or the silicon support of the silicon-containing wafer which may be referred to as the second wafer). That is, one or more of the nitride layer, the graphene layer structure and the dielectric layer of the first wafer may be patterned, and/or any layer and/or metal contacts of the second wafer. This may be done using conventional photolithography techniques and the like, and may also be used as described below to provide metal contacts.

For example, the first wafer can be patterned before the wafer bonding step in order to pattern the graphene layer structure into desired device shapes (i.e. into an array of individual devices across the wafer) together with any further layers provided on the surface which preferably retains the same shape as the graphene thereby acting as a protective cap. The underlying layer (e.g. nitride or dielectric passivation layers) may optionally be patterned at this stage too, optionally into the same shape. Alternatively, as described in exemplary embodiments herein, such patterning may be performed after wafer bonding and removal of the support of the first wafer. As will be appreciated, any layer underlying the graphene layer structure then becomes that “on” the graphene surface and any further layers or metal contacts that may have been deposited will then underly the graphene layer structure in the resulting laminate (where viewed with the silicon support at the bottom of the resulting laminate).

The second wafer may also be patterned before wafer bonding. In some preferred embodiments, the pattern is substantially the “negative” of the pattern of the first wafer in order to ensure conformal contact between the two patterned surfaces of the first and second wafers. Each wafer may further include patterning alignment markers in order to facilitate orientation and optical alignment of the two wafer surfaces for the subsequent wafer bonding step. In this way, complete device structures can be obtained without requiring further patterning after removal of the first wafer's support. As will be appreciated, further layers and/or further metal contacts may nevertheless be deposited and patterned (for example to provide a gate contact) after wafer bonding.

It is therefore also particularly preferred in some embodiments to form metal contacts in contact with the graphene layer structure prior to wafer bonding, and preferably prior to laser lift-off, for example, together with forming the dielectric passivation layer. Contacts may be deposited during the patterning step(s) (e.g. before or after patterning the graphene layer structure into the desired shape for a device).

The exposed surface of metal contacts on the first and/or second wafers may preferably be provided coplanar with the exposed surface of the surrounding material (e.g. dielectric layer or nitride layer).

Substantially flat layers are particularly preferred for wafer bonding in the absence of metal contacts in order to ensure good contact and bonding between the layers. Advantageously, complementary metal contacts (i.e. metal to metal) are typically simpler to bond together during a wafer bonding step (e.g. require lower temperatures and/or pressures which is advantageous to avoid undue damage to the other layers, and in particular the graphene layer structure). In other embodiments, the metal contacts of one of both wafers may protrude from the exposed uppermost surface. Typically, the difference in height between the metal contacts and the surface of the adjacent layers is less than 10 μm, more preferably less than 5 μm. The difference may also be at least 100 nm, at least 500 nm, or at least 1 μm.

The method comprises removing the sapphire substrate by laser-lift off. LLO is a process known in the art which involves irradiation of the interface of an appropriately transparent substrate, e.g. sapphire, and an absorbing layer. As will be understood by those skilled in the art, the laser is irradiated through the transparent substrate to ablate and evaporate the layer at the interface. Without wishing to be bound by theory, even where the nitride (sub-)layer adjacent the sapphire substrate is formed of h-BN, the two-dimensional material inevitably comprises some covalent interactions with the sapphire substrate, particularly when formed by epitaxy on the substrate, such that LLO offers a novel and unique approach to integrating a combination of a high-quality nitride and graphene layer structure into a silicon-based wafer.

As is known in the art, the wavelength of laser for LLO is selected based on the band gaps of the materials and a wavelength of about 193 nm is suitable for AlN, for example (whose band gap is about 6.0 eV). A similar wavelength may also be suitable for BN, though it is believed that an interfacial amorphous or semi-amorphous phase of h-BN may have a lower band gap (e.g. about 4.5 eV) requiring a lower energy wavelength laser (e.g. about 275 nm). Appropriate wavelengths may nevertheless be determined by those skilled in the art as a matter of routine experimentation in order to separate the sapphire substrate from the aluminium nitride or boron nitride layer.

In some embodiments, the nitride layer is etched. Methods for etching of nitrides are known in the art and any suitable method may be used. For example, nitride layers may be etched by dry-techniques such as inductively couple plasma (ICP), or reactive ion, etching. These may use chlorine-and/or fluorine-containing gases for example (Cl₂ gas is common and one exemplary gas mixture is Cl₂/BCl₃/Ar). The nitride layer may be etched by wet-techniques such as chemical etching with, for example, solutions of KOH, H₃PO₄, HF and/or TMAH. In accordance with the first aspect in which the nitride layer is wafer bonded to the silicon-containing wafer after said LLO step, the nitride layer may preferably be etched or polished after LLO so as to ensure a suitably smooth and planar surface is provided for the wafer bonding step. In accordance with the second aspect in which the resulting laminate comprises the nitride layer on the graphene layer structure, the nitride layer may preferably also be etched after removing the sapphire substrate by LLO. After etching, the nitride layer may have a thickness of less than 50 nm, preferably less than 10 nm, particularly for the second aspect whereby the nitride layer may serve as a high-quality thin gate dielectric layer in an electronic device.

In view of the foregoing, one particularly preferred embodiment is a method comprising:
providing a wafer comprising a sapphire substrate and a nitride layer, wherein the nitride layer consists of aluminium nitride and has an exposed upper surface;
forming a graphene layer structure by CVD directly on and across the exposed upper surface of the nitride layer of the wafer, wherein the graphene layer structure has an exposed upper surface;
forming a dielectric passivation layer on and across the exposed upper surface of the graphene layer structure thereby forming a wafer stack comprising, in order, a sapphire substrate, a nitride layer, a graphene layer structure and a dielectric passivation layer, wherein the dielectric passivation layer has an exposed upper surface;
forming or adhering a further layer onto the exposed upper surface of the dielectric passivation layer; and
removing the sapphire substrate by laser lift-off to expose a surface of the nitride layer distal from the graphene layer structure;
wherein:
   the method further comprises wafer bonding the exposed surface of the nitride layer to a surface of a silicon-containing wafer after the step of removing the sapphire wafer; or
   the step of forming or adhering comprises wafer bonding, and the further layer is a silicon-containing wafer.

In accordance with a further aspect of the present invention, there is provided a method for the manufacture of an electronic device, the method comprising:
providing a coated graphene layer structure on a silicon-containing wafer by any method described herein;
patterning the graphene layer structure and at least the layer thereon, e.g. the dielectric passivation layer or the nitride layer, or both; and
forming one or more electrical contacts in contact with the graphene layer structure.

As will be appreciated, such a process is particularly suitable for the manufacture of an array of electronic devices on a single wafer. Patterning of the graphene layer structure may be carried out using conventional techniques in the art of microelectronic fabrication of electronic devices, such as photolithography. Such processes are not particularly limited since the graphene is protected by the coating layer. The one or more electrical contacts may be formed so as to contact only the edge of the graphene layer structure. In some embodiments, a gate contact may be formed over the graphene layer structure on the nitride or passivation layer.

Preferably, after patterning and optionally after the formation of contacts, the method further comprises forming a dielectric coating layer, for example by ALD, across the wafer thereby encapsulating the graphene layer structure and any edges (and surfaces) of the graphene exposed by the patterning step.

Preferably the method of manufacturing an electronic device further comprises dicing the silicon-containing wafer. As will be appreciated, additional layers may also be diced simultaneously, for example any nitride layer or dielectric passivation layer which has not been patterned. Dicing is a well-known process is the art of silicon-based, e.g. CMOS, fabrication processes, which divides a wafer comprising an array of stacks of patterned semiconductor layers, each stack forming an electronic device sharing a common substrate. For example, dicing involves mechanical sawing or laser cutting.

Preferably, providing a wafer stack comprises:
(A) providing a first wafer comprising said nitride layer on said sapphire substrate, wherein the nitride layer has an exposed growth surface distal from the sapphire substrate, wherein the nitride layer has a first region extending at least 2 nm down from the exposed growth surface which satisfies the following:
   a) a dislocation density of less than 5,000 cm⁻² as measured by TEM; and
   b) a surface roughness (Ra) of less than 1 nm as measured by AFM; and
(B) forming the graphene layer structure on the exposed growth surface of the nitride layer by CVD, and forming a further layer comprising dielectric material on the graphene layer structure to form the dielectric passivation layer; and
wherein the method further comprises:
(IV) removing a portion of the nitride layer to leave a retained portion of the nitride layer formed from the first region and having a thickness of less than 20 nm.

Such steps are particularly preferred for the second aspect of the invention since the nitride layer is provided as an upper layer (i.e. on the graphene layer structure) in a resulting graphene-containing laminate. As such, the method provides a process which allows for the incorporation of a thin (less than 20 nm) layer of nitride, in particular aluminium nitride on a high-quality layer of graphene (i.e. one which would otherwise lack the essential defects and nucleation sites to permit nitride layer formation).

The first region is characterised by at least a portion of the nitride layer (that may be the entire nitride layer) which has a thickness of at least 2 nm. The dislocation density serves to characterise the high degree of single crystallinity of the first region and may be measured using conventional techniques which are known to those skilled in the art such as TEM (e.g. cross-sectional TEM). Whilst lower dislocation densities are generally preferred, such as less than 4,000 cm⁻², or less than 2,000 cm⁻², a minimal number of dislocations may still be desired since, without wishing to be bound by theory, these defect sites at the exposed surface of the nitride layer are believed to provide sites for graphene nucleation by CVD. Accordingly, a minimal defect density may be at least 1 cm⁻², at least 10 cm⁻² or at least 100 cm⁻².

The first region also has a surface roughness of less than 1 nm, which may again be measured by conventional techniques which are known to those skilled in the art such as AFM. As will be appreciated, this a measurement of the exposed growth surface of the nitride layer. Such a low surface roughness facilitates the formation of high-quality graphene by CVD. In some embodiments, the surface roughness may be less than 0.8 nm, or less than 0.6 nm. Surface roughness as used herein refers to the arithmetic average roughness, known as Ra.

Preferably the first region of the first layer extends at least 5 nm down from the exposed growth surface, preferably at least 10 nm, preferably at least 20 nm. A dislocation density is a parameter which is known in the art, though is typically used to characterise significantly thicker layers (for example GaAs layers in LED structures). Dislocation density is often measured by XRD which provides an average dislocation density across the entire layer (which can be multiple micrometers thick). In the above example of GaAs, the dislocation density across the entire layer is important for the properties of a final device. On the contrary, the present embodiment utilises a much thinner uppermost region which is retained in the final laminate. TEM is a measurement technique which allows for the measurement of the dislocation density proximal to the surface of the layer, though practically it becomes challenging to accurately measure the dislocation density in regions of less than 2 nm. As such, characterising the first region at a thickness of at least 10 nm, for example, is preferred. Since the portion of the nitride layer retained in the resulting laminate is 20 nm or less, it is sufficient for the first region to extend up to 20 nm (e.g. from 2 nm to 20 nm or from 10 nm to 20 nm) down from the exposed growth surface (though may of course extend further).

As described herein, the method may comprise removing a portion of the nitride layer (and optionally the first region) in order to provide a thin nitride layer of less than 20 nm. In some preferred embodiments, the thickness of the nitride layer and/or the first region thereof are such that the method does not involve removing a portion subsequently. For example, a nitride layer formed of a single material may have a thickness of about 5 nm, the entirety of the first layer meeting the requirements of the first region and the entire layer may be used as a layer in a final device without having to remove a portion thereof in the later steps described herein.

In accordance with a further aspect, the present invention provides a graphene-containing laminate comprising, in order:
(i) an optional silicon support;
(ii) a primary dielectric layer;
(iii) a graphene layer structure; and
(iv) a nitride layer having a thickness of less than 20 nm and wherein the nitride layer has a dislocation density of less than 5,000 cm⁻² as measured by TEM;
wherein the nitride layer comprises a primary surface directly adjacent the graphene layer structure and a secondary exposed upper surface, wherein the primary and secondary surfaces are each independently formed of aluminium nitride or boron nitride; and
wherein there is further provided one or more further dielectric layers between the primary dielectric layer and the graphene layer structure.

The graphene having been grown by CVD directly on the secondary dielectric layer therefore avoids physical transfer processing. The physical transfer of graphene, usually from copper substrates, can introduce numerous defects which negatively impacts the physical and electronic properties of graphene. As such, a person skilled in the art can readily ascertain whether a graphene layer structure, and by extension a graphene-containing laminate is one comprising a CVD-grown graphene layer structure that has been grown directly using conventional techniques in the art such as AFM and energy dispersive X-ray (EDX) spectroscopy. The graphene layer structure is devoid of metal, in particular copper, contamination and devoid of organic polymer residues by virtue of the complete absence of these materials in the process of obtaining the graphene-containing laminate. Furthermore, such processing is not suitable for large scale manufacture (such as on CMOS substrates in fabrication plants). Unintentional doping, particularly from the catalytic metal substrates together with the etching solutions, also results in the production of graphene which is not sufficiently consistent from sample to sample as is required for commercial production of electronic devices.

The primary dielectric layer is a layer which originates from the silicon-containing wafer as described in respect of the method allowing for the removal of the underlying silicon support. In some embodiments, the silicon support and primary dielectric layer are provided in the form of a CMOS wafer. The one or more further dielectric layers originate from the dielectric passivation layer as described in respect of the method.

### FIGURES

The present invention will now be described further with reference to the following non-limiting Figures, in which:

FIG. 1 illustrates a process of providing a wafer stack suitable for use in the present invention.

FIG. 2 illustrates one method of the present invention which uses the wafer stack provided by the process in FIG. 1.

FIG. 3 illustrates an exemplary manufacture of an electronic device from the graphene-containing laminate provided by the method in FIG. 2.

FIG. 4 illustrates a further method of the present invention.

The Figures illustrate methods of manufacture in which the wafer is shown in cross-section.

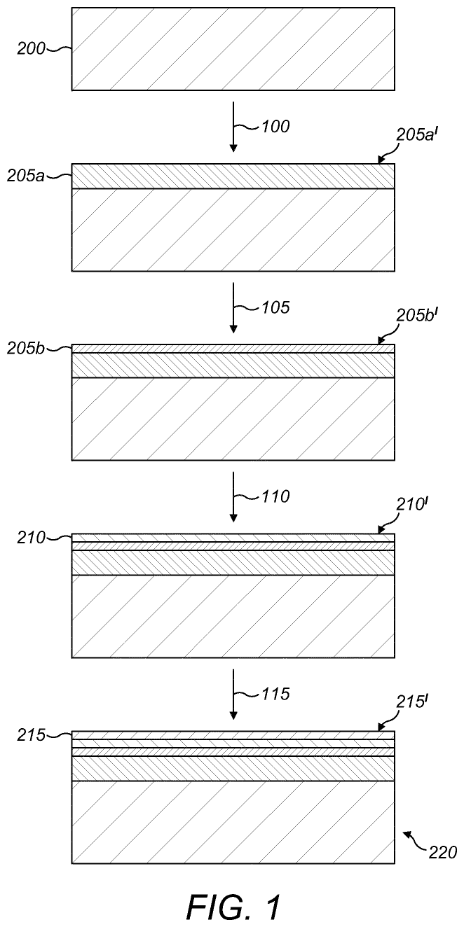

FIG. 1 illustrates an exemplary process of providing a wafer stack 220 suitable for use in the present invention. In a first step 100, a layer of aluminium nitride 205a is formed on a surface of a sapphire substrate 200 by MOCVD to a thickness of more than 150 nm. In a second step 105, a layer of h-BN 205b is formed in-situ by MOCVD thereby forming a nitride layer 205a, 205b whereby the aluminium nitride layer 205a has a surface 205a′ directly adjacent the sapphire substrate 200.

A graphene monolayer 210 is then formed in a third step 110 in-situ on the exposed upper surface 205b′ of the h-BN layer 205b at a temperature of greater than 700° C., and in a fourth step 115, a dielectric passivation layer 215 is formed on the exposed surface 210′ of the graphene monolayer 210 thereby forming a coating. Preferably, the further layer 215 comprises molybdenum oxide having a thickness of up to about 5 nm on the graphene monolayer 210, and may comprise a further layer thereon, such as aluminium oxide. The resulting wafer stack 220 has an exposed upper surface 215′ provided by the dielectric passivation layer 215.

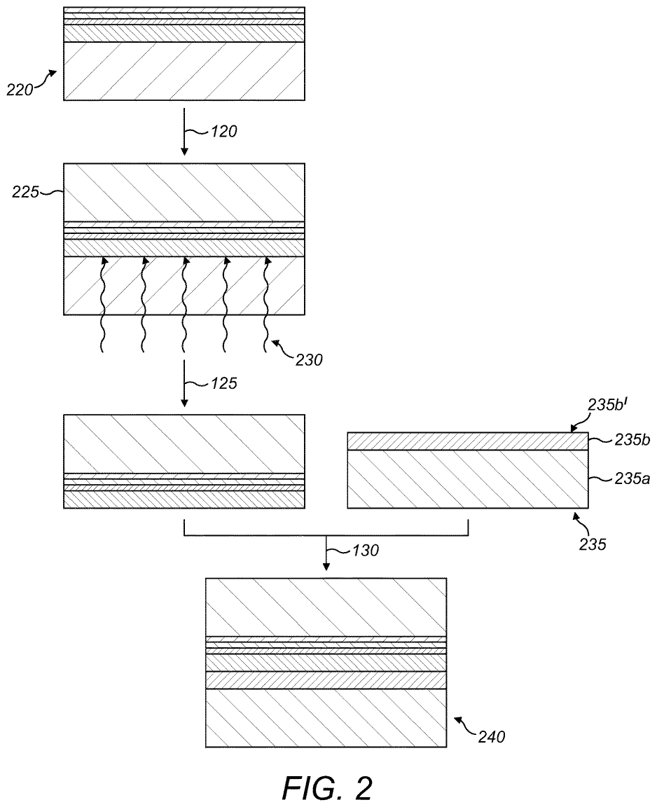

FIG. 2 illustrates an exemplary method according to the first aspect of the present invention which uses the wafer stack 220 provided by the process in FIG. 1. A sacrificial layer of etchable metal 225, for example nickel, is formed or adhered to the exposed upper surface 215′ of the dielectric passivation layer 215 in step 120. The sapphire substrate 200 is then removed in step 125 by irradiating the interface of the sapphire substrate 200 and the aluminium nitride layer 205a with a laser suitable for decomposing the aluminium nitride surface 205a′. For example, an ArF pulsed excimer laser having a wavelength of about 193 nm is suitable whereby the laser irradiation 230 passes through the wide band gap sapphire substrate 200 and is absorbed by the aluminium nitride 205a.

The exposed surface of the aluminium nitride layer 205a may be etched or polished before a step 130 of wafer bonding to a surface 235b′ of a silicon-containing wafer 235. The wafer 235 may comprise a silicon support 235a having a dielectric upper layer 235b such as silicon oxide. The silicon-containing wafer is not particularly limited and many suitable variations will be known to those skilled in the art and may be selected depending on the intended final device application. The wafer bonding step 130 results in a coated graphene layer structure on a silicon-containing wafer (i.e. a graphene-containing laminate) 240.

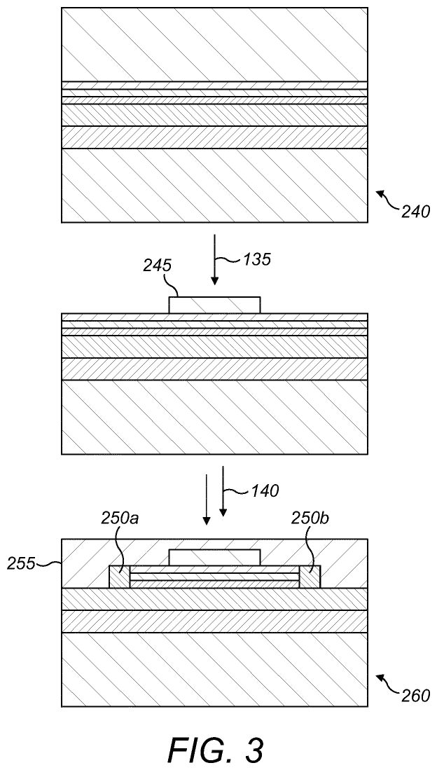

FIG. 3 illustrates an exemplary manufacture process of a transistor 260 from the graphene-containing laminate 240 provided by the method in FIG. 2. One advantage of a method according to the first aspect lies in the option to etch the sacrificial metal layer in a step 135 to provide an electrical contact 245 for an electronic device, such as a gate contact. The resulting wafer may be processed in one or more further steps 140 using conventional fabrication processes such as photolithography to deposit further electrical contacts 250a, 250b which may serve as source and drain contacts. These contacts each contact with at least an edge of the graphene monolayer 210 (together with at least an edge of the dielectric passivation layer 215 and h-BN layer 205b) thereby forming a transistor 260. The dielectric passivation layer 215 and h-BN layer 205b may be co-patterned so as to have the same shape as the graphene monolayer 210. The transistor 260 further comprises a coating layer 255 across the entire wafer, and may be formed by ALD and/or of aluminium oxide, for example. Whilst only one device is shown, it will be appreciated that the process may manufacture an array of devices which share a common underlying substrate (silicon support 235a) and each device may be separated by dicing for packaging.

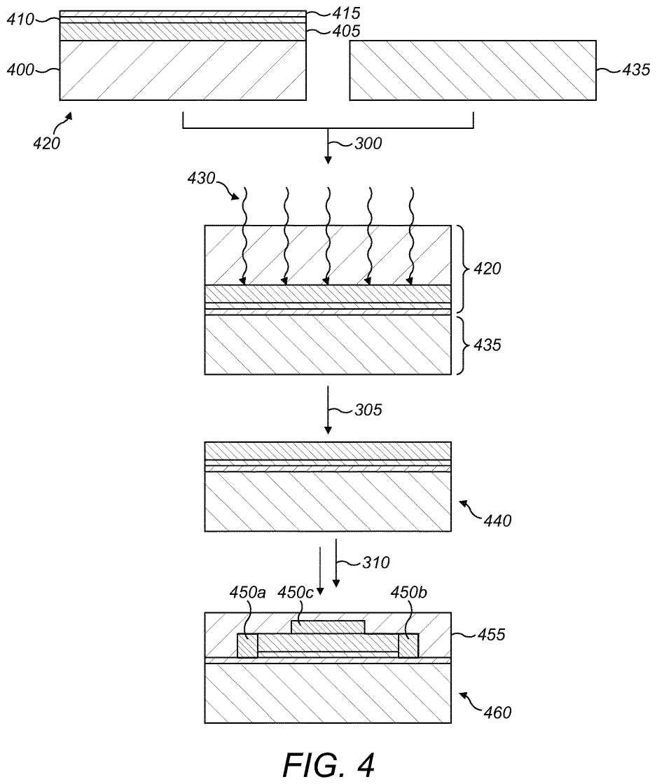

FIG. 4 illustrates an exemplary method according to the second aspect of the present invention which uses a wafer stack 420 formed of, in order, a sapphire substrate 400, a nitride layer 405 consisting of aluminium nitride, a CVD-grown graphene monolayer 410 and a dielectric passivation layer 415.

In the embodiment of FIG. 4, the wafer stack 420 is wafer bonded in step 300 via the dielectric passivation layer 415 to the surface of a CMOS wafer 435. Laser irradiation 430 is applied in a laser-lift off step 305 (as described above in respect of FIG. 2) thereby removing the sapphire substrate 400 affording a graphene-containing laminate 440 which comprises a graphene monolayer 410 coated with a high quality nitride layer 405. The laminate 440 may be processed (as described above in respect of FIG. 3) in one or more steps 310 using known microfabrication processes to deposit source, drain and gate contacts 450a, 450b, and 450c, respectively, as well as a dielectric coating 455 thereby encapsulating the components of the transistor 460. Preferably, the nitride layer 405 is etched prior to deposition of the gate contact 450c, for example to a thickness of 20 nm of less thereby retaining the uppermost region, and highest quality portion, of the nitride layer 405 of the wafer stack 420.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, “primary”, “secondary” etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material, or between layers of a wafer described “in order”. Spatially relative terms, such as “under”, “below”, “beneath”, “lower”, “over”, “above”, “upper” and the like, may be used herein for ease of description to describe one element or feature's relationship to another element(s) or feature(s). It will be understood that the spatially relative terms are intended to encompass different orientations of a wafer/laminate/device in use or operation in addition to the orientation depicted in the figures. For example, if the wafer/laminate/device as described herein is turned over, elements described as “under” or “below” other elements or features would then be oriented “over” or “above” the other elements or features. Thus, the example term “under” can encompass both an orientation of over and under. The wafer/laminate/device may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A method for the provision of a coated graphene layer structure on a silicon-containing wafer, the method comprising:
(i) providing a wafer stack comprising, in order, a substrate having a band gap of 6.5 eV or more, a nitride layer, a graphene layer structure and a dielectric passivation layer, wherein the dielectric passivation layer has an exposed upper surface;
(ii) forming or adhering a further layer onto the exposed upper surface of the dielectric passivation layer;
(iii) removing the substrate by laser lift-off to expose a surface of the nitride layer distal from the graphene layer structure; and
(iv) wafer bonding the exposed surface of the nitride layer to a surface of a silicon-containing wafer;
wherein the nitride layer of the wafer stack comprises: a first surface adjacent the substrate and a second surface adjacent the graphene layer structure, wherein the first and second surfaces are each independently formed of aluminium nitride or boron nitride.

2. The method according to claim 1, wherein the wafer stack is provided by forming the graphene layer structure by CVD directly on the nitride layer of a wafer comprising said substrate and said nitride layer.

3. The method according to claim 1, wherein the graphene layer structure is a graphene monolayer.

4. The method according to claim 1, wherein the substrate is sapphire.

5. The method according to claim 1, wherein the nitride layer of the wafer stack is provided by forming the nitride layer directly on the substrate by epitaxy.

6. The method according to claim 1, wherein the nitride layer consists of aluminium nitride or boron nitride.

7. The method according to claim 1, wherein the nitride layer is formed of a first sub-layer of aluminium nitride or boron nitride providing the first surface, a second sub-layer of aluminium nitride or boron nitride providing the second surface, and one or more further sub-layers therebetween formed of metal nitride.

8. The method according to claim 1, wherein the boron nitride is hexagonal boron nitride.

9. The method according to claim 1, wherein the nitride layer of the wafer stack has a thickness of from 100 nm to 10 μm and is etched after removing the substrate to a thickness of less than 50 nm.

10. (canceled)

11. The method according to claim 1, wherein the dielectric passivation layer has a thickness of from 0.5 nm to 500 nm.

12. The method according to claim 1, wherein the dielectric passivation layer is formed of inorganic oxide, nitride, carbide, fluoride or sulphide.

13. The method according to claim 1, wherein the dielectric passivation layer is formed of two or more sub-layers comprising a first sub-layer formed of a transition metal dichalcogenide or molybdenum oxide, and wherein the first sub-layer is provided on the graphene layer structure.

14-15. (canceled)

16. The method according to claim 1, wherein the further layer is formed of metal and is etched to form a gate contact.

17. (canceled)

18. The method according to claim 1, wherein the silicon-containing wafer comprises a layer of silicon oxide and/or silicon nitride, wherein the layer of silicon oxide and/or silicon nitride provides the surface of the silicon-containing wafer to which the nitride layer of the wafer stack is wafer bonded.

19. The method according to claim 18, wherein the silicon oxide and/or silicon nitride has a thickness of from 50 to 500 nm, and wherein the silicon oxide and/or silicon nitride is provided on a support formed of silicon, the method further comprising a step of removing the silicon support after the step of wafer bonding.

20. (canceled)

21. The method according to claim 1, wherein the silicon-containing wafer is a CMOS wafer.

22. A method for the manufacture of an electronic device, the method comprising:
providing a coated graphene layer structure on a silicon-containing wafer by the method according to any preceding claim;
patterning the graphene layer structure and dielectric passivation layer; and
forming one or more electrical contacts in contact with the graphene layer structure.

23. The method according to claim 22, further comprising dicing the silicon-containing wafer.

24. A method for the provision of a coated graphene layer structure on a silicon-containing wafer, the method comprising:
(I) providing a wafer stack comprising, in order, a substrate having a band gap of 6.5 eV or more, a nitride layer, a graphene layer structure and a dielectric passivation layer, wherein the dielectric passivation layer has an exposed upper surface;
(II) wafer bonding the exposed upper surface of the dielectric passivation layer to a surface of a silicon-containing wafer; and
(III) removing the substrate by laser lift-off to expose a surface of the nitride layer distal from the graphene layer structure;
wherein the nitride layer of the wafer stack comprises a first surface directly adjacent the substrate and a second surface directly adjacent the graphene layer structure, wherein the first and second surfaces are each independently formed of aluminium nitride or boron nitride.

25. The method according to claim 24, wherein:
step (I) of providing a wafer stack comprises:
(A) providing a first wafer comprising said nitride layer on said substrate, wherein the nitride layer has an exposed growth surface distal from the substrate, wherein the nitride layer has a first region extending at least 2 nm down from the exposed growth surface which satisfies the following:
a) a dislocation density of less than 5,000 cm⁻² as measured by TEM; and
b) a surface roughness (Ra) of less than 1 nm as measured by AFM; and
(B) forming the graphene layer structure on the exposed growth surface of the nitride layer by CVD, and forming a further layer comprising dielectric material on the graphene layer structure to form the dielectric passivation layer; and
wherein the method further comprises:
(IV) removing a portion of the nitride layer to leave a retained portion of the nitride layer formed from the first region and having a thickness of less than 20 nm.

26-28. (canceled)
